(19) United States
(12) Patent Application Publication
(10) Pub. No.: US 2025/0264657 A1
(43) Pub. Date: Aug. 21, 2025

(54) MULTICORE FIBER GEOMETRY AND ISOTROPIC COOLING ENVIRONMENT MITIGATING THERMAL GRADIENTS IN COHERENT BEAM COMBINING

(71) Applicant: Lumentum Operations LLC, San Jose, CA (US)

(72) Inventors: Benedikt HERMANN, Zurich (CH); Peter JAKOPIC, Videm-Dobrepolje (SI); Žan PIRNAR, Ljubljana (SI); Simonette PIERROT, Zurich (CH)

(21) Appl. No.: 18/738,938

(22) Filed: Jun. 10, 2024

Related U.S. Application Data
(60) Provisional application No. 63/553,886, filed on Feb. 15, 2024.

(51) Int. Cl. G02B 6/036; F28F 3/12; G02B 6/024; G02B 27/10

(52) U.S. Cl. CPC G02B 6/036; F28F 3/12; G02B 6/024; G02B 27/10

(57) ABSTRACT

In some implementations, an optical system comprises a multicore fiber having multiple cores arranged along one or more isotherms and an isotropic cooling environment housing the multicore fiber. In some implementations, the isotropic cooling environment includes a cold plate having a groove shaped to fit the multicore fiber and a structure to enclose the multicore fiber within the groove.

### CROSS-REFERENCE TO RELATED APPLICATION

This Patent Application claims priority to U.S. Provisional Patent Application No. 63/553,886, filed on Feb. 15, 2024, and entitled “MULTI-CORE FIBER GEOMETRY WITHOUT THERMAL GRADIENTS FOR COHERENT BEAM COMBINING.” The disclosure of the prior Application is considered part of and is incorporated by reference into this Patent Application.

### TECHNICAL FIELD

The present disclosure relates generally to coherent beam combining, and to a multicore fiber geometry and isotropic cooling environment to mitigate temperature gradients that may otherwise contribute to a group delay mismatch.

### BACKGROUND

Coherent beam combining (CBC) is a technique used in optics to merge multiple laser beams into a single output beam with higher power and/or a desired beam quality. CBC is particularly useful in applications where the power of a single laser is insufficient, and scaling the power of a single emitter is challenging due to physical and/or technological limitations. The fundamental principle of CBC involves the superposition of individual laser beams in a manner that results in constructive interference, which in turn increases the intensity of the combined beam. To achieve the increase in intensity, the phase and amplitude of each individual laser beam needs to be carefully controlled. For example, the phase and/or amplitude control may be accomplished through active and/or passive phase-locking mechanisms, which can include electronic feedback systems that adjust the phases of the lasers in real-time based on the observed interference pattern of the beams. The implementation of CBC can be categorized into two main architectures: tiled-aperture combining and filled-aperture combining. In tiled-aperture combining, individual laser beams are arranged in a two-dimensional array, and phases of the laser beams are controlled to constructively interfere at a distant target, effectively creating a single high-power beam. The tiled-aperture approach is beneficial in high-power laser systems, such as those used in directed energy applications. Filled-aperture combining involves overlapping the beams in the same spatial mode of a single aperture, which is advantageous for applications requiring high beam quality and brightness, such as in fiber laser systems. However, CBC poses challenges, including the need to control a group delay and a phase delay to maintain coherence (e.g., for pulsed lasers), and the complexity of scaling the system with a large number of emitters.

### SUMMARY

In some implementations, an optical system includes a multicore fiber having a central axis and multiple cores that are equidistant from the central axis and arranged in a symmetric pattern with respect to the central axis; and an isotropic cooling environment housing the multicore fiber, wherein the isotropic cooling environment includes: a cold plate having a groove shaped to fit the multicore fiber; and a covering structure to enclose the multicore fiber within the groove.

In some implementations, an optical system includes a multicore fiber having multiple cores arranged along one or more isotherms; and an isotropic cooling environment housing the multicore fiber, wherein the isotropic cooling environment includes: a cold plate having a groove shaped to fit the multicore fiber; and a structure to enclose the multicore fiber within the groove.

In some implementations, a coherent beam combining system includes a laser source configured to generate a seed laser; a division stage comprising one or more optical devices configured to divide the seed laser into a beam array that comprises multiple input beams; a multicore fiber to receive the multiple input beams, wherein the multicore fiber includes multiple cores arranged along one or more isotherms; an isotropic cooling environment housing the multicore fiber, wherein the isotropic cooling environment includes: a cold plate having a groove shaped to fit the multicore fiber; and a structure to enclose the multicore fiber within the groove; an amplification stage comprising multiple amplifiers configured to amplify the multiple input beams to generate multiple amplified beams; and a combination stage comprising one or more optical devices configured to combine the multiple amplified beams into a single output beam.

### BRIEF DESCRIPTION OF THE DRAWINGS

FIG. 1 is a diagram illustrating an example of controlling a group delay and a phase delay in a coherent beam combining system.

FIG. 2 is a diagram illustrating an example of a multicore fiber geometry that induces thermal gradients and an example implementation of a multicore fiber geometry that mitigates thermal gradients.

FIG. 3 is a diagram illustrating an example implementation of a multicore fiber geometry and isotropic cooling environment for mitigating thermal gradients in a coherent beam combining system.

FIG. 4 is a diagram illustrating example implementations of a polarization-maintaining multicore fiber having a geometry for mitigating thermal gradients.

FIG. 5 is a diagram illustrating an example of a coherent beam combining system.

### DETAILED DESCRIPTION

The following detailed description of example implementations refers to the accompanying drawings. The same reference numbers in different drawings may identify the same or similar elements.

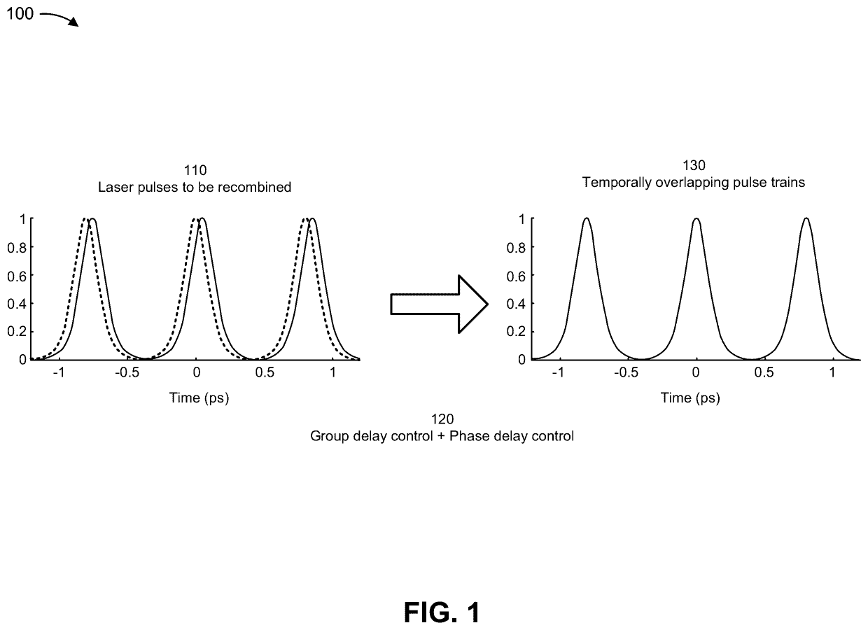

FIG. 1 is a diagram illustrating an example 100 of controlling a group delay and a phase delay in a coherent beam combining system.

Fiber laser technology has many properties that are useful for various light-induced applications in science, industry, and other fields. For example, fiber laser systems have characteristics that enable power scaling, excellent beam quality and stability, high quantum efficiency, wide gain bandwidth, and/or thermal management, which has resulted in fiber laser systems often being used for versatile laser sources in continuous wave (CW) and pulsed regimes. For example, because fiber laser systems enable power scaling, fiber laser systems are often used in applications that demand high power levels (e.g., in a kilowatt (kW) regime), such as advanced material processing and laser particle accelerators, among other examples. For example, fiber laser systems using high-brightness laser diodes and double-cladding fibers can offer significantly higher output powers than fiber laser systems that pump through single-clad fibers, and chirped pulse amplification techniques enable further power scaling for ultrafast (e.g., femtosecond) pulses in single amplification channels (e.g., single core amplifiers).

However, ultrafast fiber laser technology is approaching a power scaling limit of single core amplifiers due to various physical limitations, which include nonlinear effects, polarization losses, mode instabilities, thermal issues, optical damage, and/or pump power limitations. Accordingly, in some cases, beam combining techniques may be used to enable further power scaling in a fiber laser system. For example, beam combining techniques may use several fibers or several cores to split a seed laser beam before an amplification stage to distribute the intensity of the beam over the several fibers or several cores, and the various beams (or beamlets) are then individually amplified and combined into a single output. In general, the amplification can be performed using multiple amplifier channels, which can be individual fibers or a multicore fiber (MCF) where multiple cores are embedded within a single larger fiber and the beams are amplified in parallel before being recombined. However, fiber-based amplifiers for ultra-fast lasers are reaching intensity limitations due to non-linearities inside an active core, which lead to self-phase modulation that causes beam quality degradation.

Accordingly, coherent beam combining (CBC) techniques may be used to (re)combine multiple beams more efficiently. For example, in a CBC system, power scaling may be achieved by combining multiple laser amplifiers that are seeded by a common laser source into a single high-power output beam while maintaining beam quality and preserving spatial and spectral properties of the lasers. For example, in a CBC system, there is a phase relation between the multiple laser amplifiers, with parallel amplifiers effectively operating as a single laser. The general notion is that a seed beam is split into several replicas (e.g., N channels) that are then amplified to the highest possible power and/or energy through the parallel amplifier sections, and the amplified replicas of the seed beam are then combined into a single beam. By spatially multiplexing a seed laser through multiple individual cores (and/or fibers) and coherent re-combination, peak intensity limits can be overcome. However, to maximize the combining efficiency and avoid intensity fluctuations, temporal delays (e.g., phase differences) between beamlets in different cores or different fibers need to be stabilized down to a fraction of a wavelength. For example, a CBC system may use active phase control, where a phase detector is used at an output side of the amplifier stage to detect phase differences between neighboring beams, and a phase modulator is used (e.g., prior to or after the amplification stage) to correct the phase differences that are detected using the phase detector. However, before phase control can be performed to produce efficient recombination interference conditions, a group delay (e.g., an arrival time difference) needs to be sufficiently small to avoid a temporal mismatch that may otherwise lead to a loss of coherence between beamlets. For example, for ultra-short pulses, a group delay (or arrival time difference) between individual beams (or beamlets) needs to be at least one order of magnitude shorter than a pulse length.

More particularly, group delay is generally induced by optical path differences (OPDs) that may originate from factors such as variations in a fiber length and/or variations in a refractive index, which may be manufacturing-related or thermally-induced. To produce efficient recombination interference conditions, phase control needs to provide a group delay that satisfies (e.g., is less than) a threshold. Otherwise, a temporal mismatch will lead to a loss of coherence between beamlets. For example, in FIG. 1, plot 110 corresponds to two pulse trains (e.g., associated with respective beams) associated with a first OPD (e.g., 15 micrometers (μm)) and a first temporal overlap (e.g., a 78% overlap). Accordingly, as shown by reference number 120, a CBC system may implement group delay control and phase delay control to compensate for the OPD and produce two temporally overlapping pulse trains. For example, the group delay control may provide OPD coarse tuning to ensure that the two pulse trains overlap temporally, such that the OPD satisfies a first threshold, ensuring that the temporal overlap satisfies a second threshold (e.g., such that the two pulse trains in plot 110 have an OPD below 7 μm to ensure that the two pulse trains have at least a 90% temporal overlap). The phase delay control may then perform OPD fine tuning to ensure that the pulses constructively interfere (e.g., providing additional fine tuning within a 2π range, with at least a λ/10 resolution, where λ is a wavelength). In this way, as shown in plot 130, the two pulse trains may have an OPD that enables coherent beam combining (e.g., an OPD of 0 μm, resulting in a 100% temporal overlap).

Accordingly, to maintain coherence between beamlets in a CBC system, reducing a group delay mismatch (e.g., to a threshold level) is a prerequisite to avoiding a temporal mismatch and enabling phase delay control that produces efficient recombination (constructive) interference conditions. In some cases, group delay compensation may be performed using active techniques, such as piezo actuators and/or other linear delay stages equipped with one or more retro-mirrors. However, using active techniques to reduce group delay mismatch increases the size, cost, and complexity associated with a CBC system. Accordingly, some implementations described herein relate to one or more passive techniques that may be used to reduce a group delay mismatch. For example, as described in further detail herein, a multicore fiber may include multiple cores that are arranged according to a geometry that may eliminate or reduce temperature variations among the multiple cores (e.g., that may cause refractive index variations contributing to an OPD). In some implementations, the multicore fiber may be used in combination with one or more other passive techniques to reduce the group delay mismatch. For example, in some implementations, the multicore fiber may be mounted or housed in an isotropic cooling environment, such as a cold plate with a groove design, to efficiently extract heat from the multicore fiber and reduce absolute temperatures and gradients, and thereby enable power scaling. Additionally, or alternatively, in some implementations, the multicore fiber may have a symmetric bending layout to eliminate or reduce geometry-induced OPD. In this way, some implementations described herein may reduce a group delay mismatch in a CBC system and ensure that beams or beamlets to be recombined have a temporal overlap that enables fine-tuned phase delay control.

FIG. 1 is provided as an example. Other examples may differ from what is described with regard to FIG. 1.

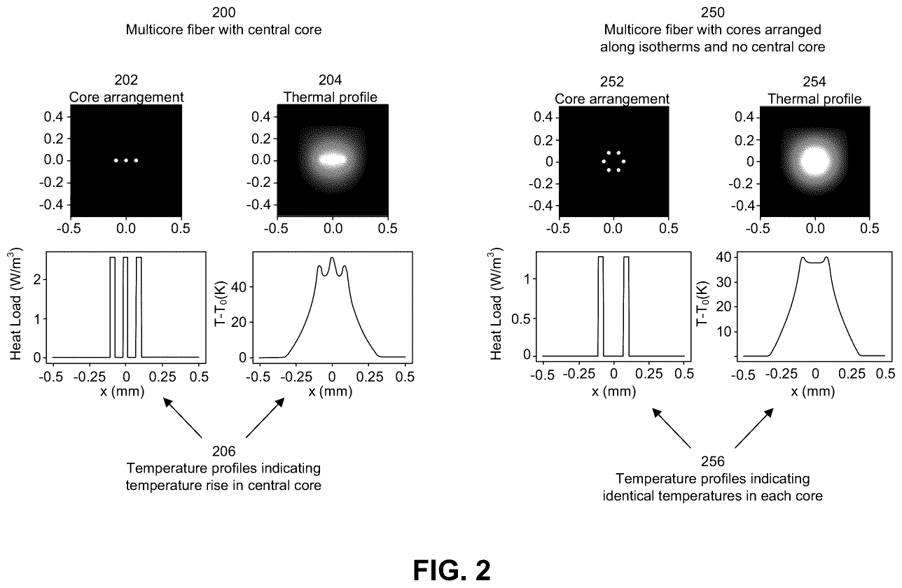

FIG. 2 is a diagram illustrating an example 200 of a multicore fiber geometry that induces thermal gradients and an example implementation 250 of a multicore fiber geometry that mitigates thermal gradients. For example, as described herein, multiple beams or beamlets to be combined in a CBC system may exhibit a group delay that may be induced by OPDs. In a multicore fiber with multiple cores, beams or beamlets propagating in the respective cores may be associated with OPDs that are caused by factors such as variations in a refractive index. Furthermore, in some cases, refractive index variations among the cores in a multicore fiber may be caused by thermal gradients (e.g., temperature differences in the respective cores). For example, in a multicore fiber that includes a geometry with one or more central (or inner) cores and one or more outer cores (e.g., a square array, three cores arranged in a line, a ring of cores surrounding a central core, or the like), the central or inner cores tend to exhibit higher temperatures than the outer cores. As a result, the core geometry in a multicore fiber can cause thermal gradients, which may lead to refractive index variations that may increase a group delay mismatch. The group delay mismatch may severely deteriorate recombination efficiency and output pulse duration for sub-picosecond (ps) laser pulses.

For example, FIG. 2 depicts an example 200 of a multicore fiber geometry with one or more central cores, which may induce thermal gradients. For example, the multicore fiber includes a core arrangement 202 with three cores, which produces a temperature profile 204 (shown as a finite-element (FE) simulation) inside a multicore fiber. As shown by reference number 206, the geometry with a three-core layout and a central core exhibits a temperature rise in the central core. For example, reference number 206 refers to a first plot in which a vertical or y-axis depicts a heat load (in watts (W) per cubic meter (m)), with the horizontal or x-axis corresponding to x-coordinates along which heat flows (e.g., generally corresponding to the x-coordinates of the three cores). In addition, reference number 206 refers to a second plot in which a vertical or y-axis depicts a temperature difference (e.g., using the notation T−T₀(K)). For example, the second plot depicts the temperature difference with respect to a material (e.g., a cold plate) surrounding the multicore fiber with the three-core layout and central core, corresponding to a temperature rise that occurs when the multicore fiber is active.

In general, typical values for a thermo-optic coefficient (e.g., a change in refractive index with respect to temperature at a constant pressure, expressed as dn/dT) for glass and yttrium aluminum garnet (YAG) are 10⁻⁵ Kelvin⁻¹ (K⁻¹)). For example, a group delay mismatch for a fiber with a one-meter length and temperature differences of a few degrees K between cores may be expected to be up to a few tens of microns under certain operating conditions (e.g., pumping with ˜600 W and a peak heat load of 70 W/m³). The group delay mismatch would severely deteriorate recombination efficiency and output pulse duration for sub-ps laser pulses. For example, in example 200, the central (hotter) core may have a temporal delay of about 1 micron per 50 W pump power, which is exhibited through phase drifts during power ramping. Furthermore, although example 200 depicts a temperature gradient that may contribute to a group delay mismatch, similar temperature gradients may occur in any multicore fiber geometry with one or more central (or inner) cores and one or more outer cores (e.g., a 3×3 or larger square array, an array of concentric rings, a hexagonal layout with 7, 19, 37, or another suitable number of cores, or the like). In particular, in such cases, the heat load in the outer cores may increase the temperature in the central or inner cores, which may lead to variations in a refractive index across the multiple cores and a larger OPD that may increase a group delay mismatch.

Accordingly, in some implementations, a multicore fiber may be associated with a geometry (e.g., a core layout) that may eliminate or significantly reduce transverse temperature gradients in the multicore fiber, which may enable optimal group delay matching. For example, FIG. 2 depicts an example implementation 250 of a multicore fiber geometry with multiple cores that are arranged along one or more isotherms, and without a central core, which may provide identical temperature profiles in each core. For example, in example implementation 250, the multicore fiber includes a core arrangement 252 with six cores arranged in a circular or hexagonal layout, and without a central core, which results in a thermal profile 254 showing identical or uniform temperatures across the various cores (e.g., there are no cores that exhibit a temperature rise due to an imbalance in the number of adjacent or neighboring cores). More generally, some implementations described herein relate to a multicore fiber geometry where multiple cores are arranged along one or more isotherms, which generally correspond to one or more cross-sectional lines or points having the same temperature. For example, in cases where each core has the same diameter, the one or more isotherms may lie along a circle that surrounds the central axis of the multicore fiber, whereby the multiple cores may be equidistant from the central axis and arranged in a symmetric pattern with respect to the central axis. For example, in FIG. 2, the core arrangement 252 is a circular or hexagonal layout, although other suitable geometries may be used (e.g., a 2×2 square layout inscribed within a circle). Additionally, or alternatively, in some cases, the isotherms may be arranged in an asymmetric pattern, such as when there is a variation in the size or diameter of the various cores. For example, a temperature may be higher in a core with a relatively larger diameter, whereby the isotherms associated with the multicore fiber (e.g., locations where the temperature is identical) may result in the multiple cores being different distances from the central axis and/or arranged in an asymmetric pattern.

Accordingly, as described herein, a multicore fiber may generally include multiple fibers arranged according to a geometry that results in identical temperatures in each core. For example, as shown by reference number 256, the geometry with six cores arranged in a circular (e.g., ring) or hexagonal geometry, and with no central or inner cores, results in identical temperatures in each core. For example, reference number 256 refers to a first plot in which the vertical or y-axis depicts a heat load (in W/m³), showing two x-coordinates along which heat flows (e.g., generally corresponding to the x-coordinates of the three leftmost cores and the x-coordinates of the three rightmost cores). In addition, reference number 256 refers to a second plot in which a vertical or y-axis depicts a temperature difference (e.g., using the notation T−T₀(K)), where a first temperature difference at the x-coordinates of the three leftmost cores is identical to a second temperature difference at the x-coordinates of the three rightmost cores.

In this way, arranging multiple cores in a multicore fiber according to a geometry that results in identical temperatures in each core may eliminate or mitigate a thermally-induced group delay mismatch, which may enable phase delay control and improve performance in a CBC system (e.g., an ultra-fast CBC laser). Furthermore, in some implementations, identical temperature profiles in each core may enhance a spatial mode matching among beamlets traveling in the respective cores. For example, higher temperatures typically lead to reduced mode field diameters due to enhanced refractive index profiles (self-focusing), and mode field matching affects the recombination efficiency and output beam quality in a CBC system. Furthermore, as described in further detail herein, the multicore fiber may be embedded in an isotropic cooling environment, which may efficiently extract heat from the multicore fiber and reduce temperature gradients across the multiple cores.

FIG. 2 is provided as an example. Other examples may differ from what is described with regard to FIG. 2.

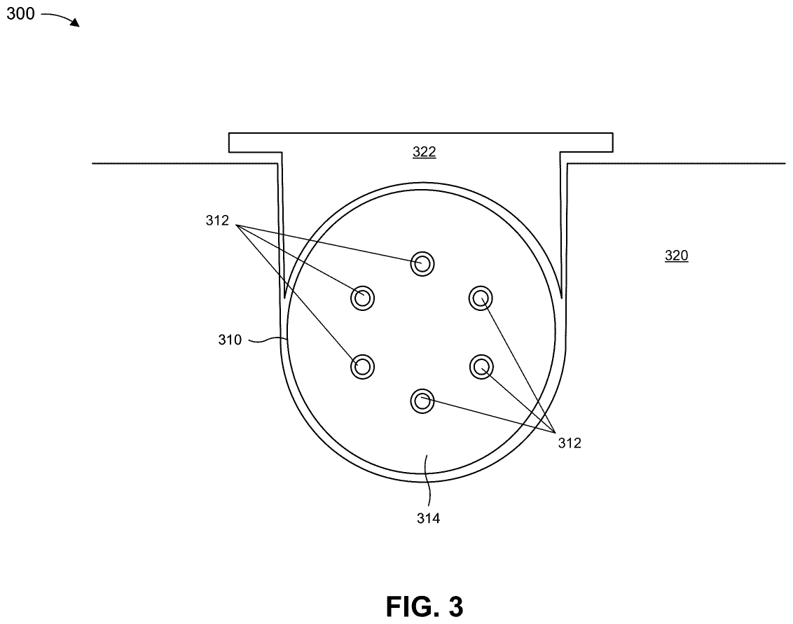

FIG. 3 is a diagram illustrating an example implementation 300 of a multicore fiber geometry and an isotropic cooling environment for mitigating thermal gradients in a CBC system. For example, as shown in FIG. 3, example implementation 300 includes a multicore fiber 310 having multiple cores 312 (e.g., doped signal cores) arranged along one or more isotherms. For example, in FIG. 3, the multicore fiber 310 includes a central axis and six cores 312 that are equidistant from the central axis and arranged in a symmetric pattern with respect to the central axis (e.g., a circular or hexagonal pattern). Alternatively, in some implementations, the multiple cores 312 may be arranged in an asymmetric pattern with respect to the central axis (e.g., where one or more cores 312 have a larger diameter or a smaller diameter relative to other cores 312 that affects the temperature within the one or more cores 312). Accordingly, as described herein, the various cores 312 may be arranged along one or more isotherms of the multicore fiber 310, in any suitable geometry that results in identical temperature profiles in each core 312. As further shown in FIG. 3, the multicore fiber 310 may include a pump region 314, and a cladding layer may surround the pump region 314 to guide pump light.

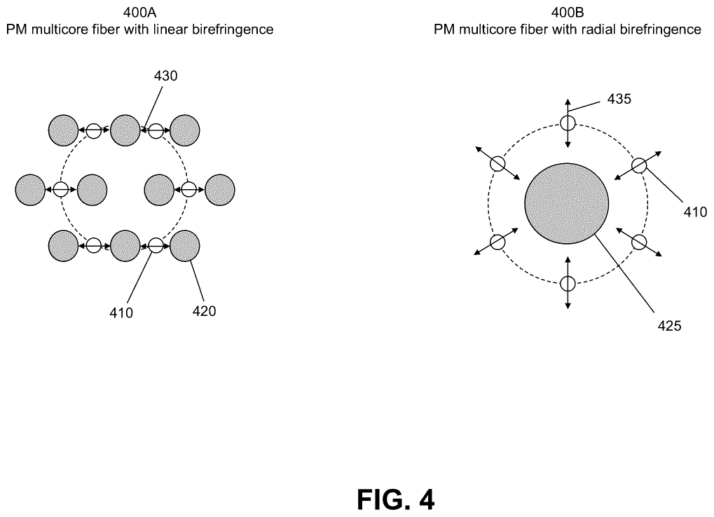

In some implementations, the cores 312 of the multicore fiber 310 may be polarization-maintaining (PM) or non-PM. For example, in some implementations, the cores 312 of the multicore fiber 310 may be made PM by creating birefringence with one or more stress rods (not shown in FIG. 3) positioned around the cores 312. For example, example layouts for the stress rods are shown in FIG. 4 and described in further detail herein. The size and refractive indexes of the individual cores 312 may determine whether the multicore fiber 310 is single-mode or multi-mode. For example, a peak intensity is lowered with a larger core diameter, but a large core diameter also results in guiding of higher order modes. Depending on an application, the diameter and/or refractive indexes of the cores 312 may be configured to ensure single-mode operation. Additionally, or alternatively, depending on the application, the diameter and/or refractive indexes of the cores 312 may be configured to ensure multi-mode operation.

As described herein, the multicore fiber 310 may arrange the multiple active cores 312 and heat sources in a ring, hexagonal, square, or other suitable symmetric geometry (e.g., when the cores 312 have identical diameters) or asymmetric geometry (e.g., when the cores 312 have different diameters or refractive indexes, such as in multi-mode operation) with the cores 312 generally arranged along one or more isotherms. In this way, the geometry of the cores 312 may eliminate or reduce temperature gradients (e.g., temperature differences) across the various cores 312. Furthermore, in some implementations, the multicore fiber 310 may be housed or mounted within a cooling environment to extract heat from the multicore fiber 310 in an isotropic or near-isotropic manner that yields identical temperatures among the various cores 312. For example, as shown in FIG. 3, the isotropic cooling environment may include a cold plate 320 (e.g., water-cooled aluminum, copper, or another suitable material) with a groove shaped to fit the multicore fiber 310. For example, in some implementations, the groove may be U-shaped to fit the circular shape of the multicore fiber 310. Furthermore, in some implementations, the isotropic cooling environment may include a covering structure 322, shown as a top lid closure, to achieve isotropic cooling. In some implementations, a metal-to-fiber gap between the multicore fiber 310 and metal of the cold plate 320 may be filled with an adhesive (e.g., glue) that is transparent (e.g., at a laser wavelength) and thermally conductive (e.g., has a thermal conductivity that satisfies a threshold associated with a heat sinking or heat extraction application). In some implementations, the adhesive may be applied in a way to ensure that no bubbles are formed in the adhesive filling the gap between the multicore fiber 310 and the cold plate 320. For example, in some implementations, the adhesive filling may be cured under vacuum conditions.

As described herein, the gap width between the multicore fiber 310 and the cold plate 320, and between the multicore fiber 310 and the covering structure 322, strongly affects heat extraction. Accordingly, in some implementations, the U-shaped groove and the covering structure 322 may be manufactured to a desired precision to ensure that dimensions of the fiber-to-metal gap around the multicore fiber 310 are uniform around a circumference of the multicore fiber 310. For example, as shown in FIG. 3, the covering structure 322 may be shaped to closely follow the shape of the multicore fiber 310 (e.g., the covering structure 322 has an upside-down U-shape in FIG. 3). Additionally, or alternatively, other cooling techniques may be used to reduce temperature variations between the multiple cores 312. For example, cooling techniques to reduce the temperature variations between the cores may include using materials with high thermal conductivities (e.g., diamond) and/or or active heat extractors (e.g., Peltier elements). In some implementations, such elements may be positioned at carefully designed locations around the multicore fiber 310 to maintain identical temperatures across the multiple cores 312. For example, in cases where heat is extracted from a first set of cores 312, that are located relatively closer to the cold plate 320, more efficiently than from a second set of cores 312, the thermally conductive materials and/or active heat extractors may be located at positions that are closer to the second set of cores 312 such that heat extraction is uniform or near-uniform in each core 312.

Accordingly, as described herein, the multicore fiber 310 may include a core arrangement or core geometry to ensure an isotropic thermal gradient. Furthermore, in some implementations, the multicore fiber 310 may be used with an isotropic cooling environment. In this way, the multicore fiber 310 and isotropic cooling environment may be suitable for applications such as high-power ultra-fast laser amplifiers that are used in CBC systems. In this way, the multicore fiber 310 and the isotropic cooling environment may define an optical system that provides passive group delay compensation.

FIG. 3 is provided as an example. Other examples may differ from what is described with regard to FIG. 3. The number and arrangement of devices shown in FIG. 3 are provided as examples. In practice, there may be additional devices, fewer devices, different devices, or differently arranged devices than those shown in FIG. 3. Furthermore, two or more devices shown in FIG. 3 may be implemented within a single device, or a single device shown in FIG. 3 may be implemented as multiple, distributed devices. Additionally, or alternatively, a set of devices shown in FIG. 3 may perform one or more functions described as being performed by another set of devices shown in FIG. 3.

FIG. 4 is a diagram illustrating example implementations 400A and 400B of a polarization-maintaining multicore fiber having a geometry for mitigating thermal gradients. For example, as described herein, a multicore fiber may have multiple cores 410 arranged along one or more isotherms (e.g., shown as dashed circles in FIG. 4) or in any suitable geometry that results in identical temperatures across the multiple cores 410 (e.g., a symmetric pattern and/or asymmetric pattern with respect to a central axis, and/or a pattern without any central or inner cores that may otherwise have a higher temperature than outer cores). Furthermore, as described herein, the cores 410 of a multicore fiber may be made PM by creating birefringence with one or more stress rods positioned around the cores 312. For example, in example 400A, a stress rod 420 (e.g., a boron-doped stress rod) may be positioned on opposite sides of core 410 to induce linear birefringence 430, and the arrangement of stress rods 420 may be repeated for each core 410 of the multicore fiber. In example 400A, one or more stress rods 420 may be positioned on the side of different cores 410. For example, in the top row of the ring, circular, or hexagonal geometry shown in example 400A, a middle stress rod 420 is placed on the left side of a first (rightmost) core 410 and on the right side of a second (leftmost) core 410. Alternatively, in example 400B, a single central stress rod 425 may be positioned along the central axis of the multicore fiber to induce radial birefringence 435. In this way, a single stress rod 425 may be used to provide the PM property, which may simplify fabrication and manufacturing of the multicore fiber.

FIG. 4 is provided as an example. Other examples may differ from what is described with regard to FIG. 4. The number and arrangement of devices shown in FIG. 4 are provided as examples. In practice, there may be additional devices, fewer devices, different devices, or differently arranged devices than those shown in FIG. 4. Furthermore, two or more devices shown in FIG. 4 may be implemented within a single device, or a single device shown in FIG. 4 may be implemented as multiple, distributed devices. Additionally, or alternatively, a set of devices shown in FIG. 4 may perform one or more functions described as being performed by another set of devices shown in FIG. 4.

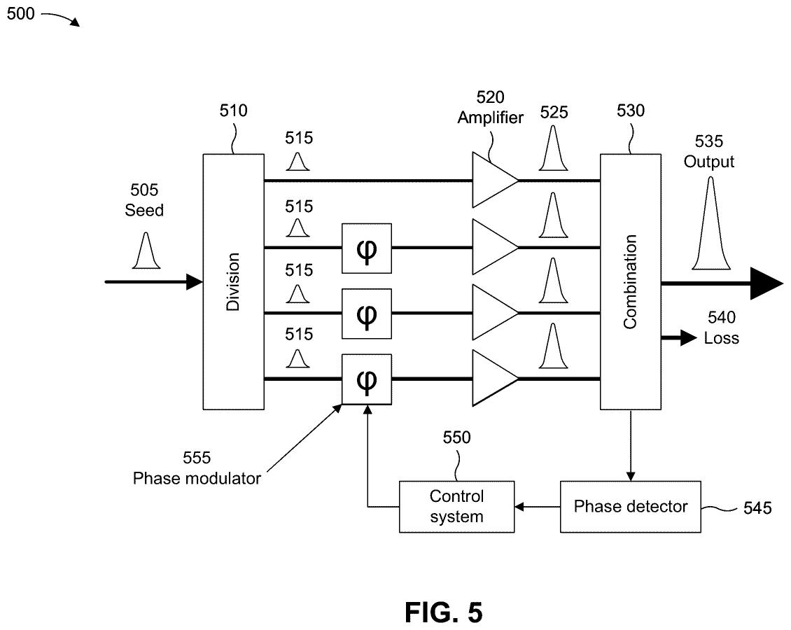

FIG. 5 is a diagram illustrating an example 500 of a CBC system. In some implementations, as described herein, the CBC system may include a multicore fiber with multiple cores that are arranged along one or more isotherms, and an isotropic cooling environment housing the multicore fiber, where the isotropic cooling environment may include a cold plate having a groove shaped to fit the multicore fiber and a covering structure to enclose the multicore fiber within the groove.

For example, in some implementations, the CBC system may include or may be coupled to a laser source configured to generate a seed laser 505. As shown in FIG. 5, the CBC system may include a division stage 510 comprising one or more optical devices configured to divide the seed laser 505 into a beam array 515 that comprises various input beams that co-propagate in parallel with a particular polarization (e.g., horizontal or vertical). As further shown in FIG. 5, the CBC system includes an amplification stage 520, which comprises multiple amplifiers that are each arranged to amplify an individual input beam in the beam array to form a set of amplified beams 525. As further shown, the CBC system 500 includes a combination stage comprising one or more optical devices configured to combine the amplified beams 525 into a single output beam 535. In addition, as shown, there may be a loss 540 of energy or power after the combination stage 530 (e.g., due to a phase delay between the various beams in the beam array 515). Accordingly, as shown in FIG. 5, a phase detector 545 may be provided after the amplification stage 520 to measure phase differences between the beams in the beam array 515. In particular, the phase detector 545 may generate one or more signals that indicate the phase differences between the beams in the beam array 515. As shown in FIG. 5, the signal(s) indicating the phase differences between the beams in the beam array 515 may be provided to a control system 550, which may control one or more phase modulators 555 to stabilize the phases of the various beams in the beam array 515 and thereby minimize the loss 540.

As described herein, in order to enable the phase control (e.g., via the phase detector 545, the control system 550, and the phase modulator 555) that results in constructive interference, a group delay associated with the various beams in the beam array 515 may need to be sufficiently small. Accordingly, in some implementations, a multicore fiber may be provided after the division stage 510 to receive the various input beams in the beam array 515, where the multicore fiber may have a design to eliminate or reduce temperature gradients across the multiple cores (e.g., in which the input beams are propagating prior to amplification). For example, as described herein, the multicore fiber includes multiple cores that are arranged along one or more isotherms, and the multiple fiber may be housed or mounted within an isotropic cooling environment to ensure uniform heat extraction across the multiple cores. For example, the isotropic cooling environment may include a cold plate having a groove shaped to fit the multicore fiber and a structure to enclose the multicore fiber within the groove. Furthermore, the multicore fiber and the isotropic cooling environment may have other features to ensure uniformity in a temperature profile across the various cores, as described elsewhere herein.

FIG. 5 is provided as an example. Other examples may differ from what is described with regard to FIG. 5. The number and arrangement of devices shown in FIG. 5 are provided as examples. In practice, there may be additional devices, fewer devices, different devices, or differently arranged devices than those shown in FIG. 5. Furthermore, two or more devices shown in FIG. 5 may be implemented within a single device, or a single device shown in FIG. 5 may be implemented as multiple, distributed devices. Additionally, or alternatively, a set of devices shown in FIG. 5 may perform one or more functions described as being performed by another set of devices shown in FIG. 5.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical system, comprising:
a multicore fiber having a central axis and multiple cores that are equidistant from the central axis and arranged in a symmetric pattern with respect to the central axis; and
an isotropic cooling environment housing the multicore fiber, wherein the isotropic cooling environment includes:
a cold plate having a groove shaped to fit the multicore fiber; and
a covering structure to enclose the multicore fiber within the groove.

2. The optical system of claim 1, wherein the multicore fiber is polarization maintaining.

3. The optical system of claim 2, wherein the multicore fiber includes multiple stress rods that are positioned such that the multiple cores each have a first stress rod and a second stress rod on opposite sides to create birefringence in the respective core.

4. The optical system of claim 2, wherein the multicore fiber includes a single stress rod that is positioned along the central axis to create radial birefringence in the multiple cores.

5. The optical system of claim 1, wherein the multicore fiber is single-mode.

6. The optical system of claim 1, wherein the multicore fiber is multi-mode.

7. The optical system of claim 1, wherein a fiber-to-metal gap is uniform around a circumference of the multicore fiber.

8. The optical system of claim 7, wherein the fiber-to-metal gap is filled with an adhesive that has a high thermal conductivity and is transparent at a laser wavelength.

9. The optical system of claim 1, wherein one or more of the cold plate or the covering structure includes one or more thermally conductive elements or a thermally conductive material such that a temperature difference between the multiple cores satisfies a threshold.

10. An optical system, comprising:
a multicore fiber having multiple cores arranged along one or more isotherms; and
an isotropic cooling environment housing the multicore fiber, wherein the isotropic cooling environment includes:
a cold plate having a groove shaped to fit the multicore fiber; and
a structure to enclose the multicore fiber within the groove.

11. The optical system of claim 10, wherein the multicore fiber has a central axis, and wherein the multiple cores are arranged in a symmetric pattern with respect to the central axis.

12. The optical system of claim 10, wherein the multicore fiber has a central axis, and wherein the multiple cores are arranged in an asymmetric pattern with respect to the central axis.

13. The optical system of claim 10, wherein the multicore fiber is polarization maintaining.

14. The optical system of claim 10, wherein the multicore fiber is single-mode.

15. The optical system of claim 10, wherein the multicore fiber is multi-mode.

16. The optical system of claim 10, wherein a fiber-to-metal gap is uniform around a circumference of the multicore fiber.

17. The optical system of claim 10, wherein one or more of the cold plate or the structure to enclose the multicore fiber includes one or more thermally conductive elements or a thermally conductive material.

18. A coherent beam combining system, comprising:
a laser source configured to generate a seed laser;
a division stage comprising one or more optical devices configured to divide the seed laser into a beam array that comprises multiple input beams;
a multicore fiber to receive the multiple input beams, wherein the multicore fiber includes multiple cores arranged along one or more isotherms;
an isotropic cooling environment housing the multicore fiber, wherein the isotropic cooling environment includes:
a cold plate having a groove shaped to fit the multicore fiber; and
a structure to enclose the multicore fiber within the groove;
an amplification stage comprising multiple amplifiers configured to amplify the multiple input beams to generate multiple amplified beams; and
a combination stage comprising one or more optical devices configured to combine the multiple amplified beams into a single output beam.

19. The coherent beam combining system of claim 18, wherein the multiple cores are arranged in a symmetric pattern with respect to a central axis of the multicore fiber.

20. The coherent beam combining system of claim 18, wherein the multiple cores are arranged in an asymmetric pattern with respect to a central axis of the multicore fiber.
